(19) United States
(12) Patent Application Publication
(10) Pub. No.: US 2002/0166228 A1
(43) Pub. Date: Nov. 14, 2002

(54) Process for integrated PC board

(75) Inventor: Canny Wang, Taipei (TW)

Correspondence Address: DOUGHERTY & TROXELL, SUITE 1404, 5205 LEESBURG PIKE, FALLS CHURCH, VA, 22041, US

(73) Assignee: PATEN Technology Corporation

(21) Appl. No.: 09/850,100

(22) Filed: May 8, 2001

(51) Int. Cl. H05K 3/36

(52) U.S. Cl. 29/830; 29/412

(57) ABSTRACT

A process for integrated PC board, which includes: (a) supplying an integrated PC board. The integrated PC board is to integrate plural sub-boards to one single board in a device. There are plural elements on the integrated board with plural folding lines for partitioning plural areas for being as sub-boards; (b) folding and breaking the plural folding lines to dismantle the integrated board to plural sub-boards, and the sub-boards are able to offer complete function after assembling.

### FIELD OF THE INVENTION

The invention is related to a process for integrated PC board, especially the process for simplifying multi-layer to single layer integrated PC board.

### BACKGROUND OF THE INVENTION

Please refer to the series of FIG. 1 to FIG. 4.

In prior art, there are plural sub-boards 211 installed inside device 1, and there are plural elements 22 designed on each sub-board 211. These plural elements 22 are including many kinds of elements. Different steps manufacture the different elements 22, thus each sub-board 211 is formed after these steps.

For example, elements 22 are at least including two sorts of elements, which are SMT (Surface Mounting Technology) element and T/H (Through Hole) element, and either of them is manufactured by related steps to be mounted on board.

In case of device 1 including more than one sub-board 211, the mentioned mounting steps are necessary to be repeated. The shortness is as following:

Firstly, the steps for sub-boards 211 in device 1 are complicate. The reason is that for reaching functions of device 1, the steps for manufacturing sub-boards 211 are repeated to produce plural sub-boards 211. Secondly, sub-boards 211 in device 1 are manufactured separately, and enough room in device 1 for sub-boards 211 is a need. On the other hand, assembly factory needs more space for storing.

### SUMMARY OF THE INVENTION

The main object is to offer a process for that integrating the prior art design to a single integrated PC board, wherein the prior art design means plural sub-boards installed in a single device.

Firstly, there are several folding lines on a single board for partitioning to plural areas for being as sub-boards, thus each sub-board can be mounted the elements that the sub-board needs, and therefore it is not necessary to repeat some same steps when mounting same elements on different and separate sub-boards.

Secondly, when assembly, the integrated board can be partitioned to plural sub-boards from the folding lines. It saves a lot of time because the integrated board can be taken apart to plural sub-boards from the plural folding lines for fast assembly sub-boards in a device. The assembly for old fashion is that picking up different sub-boards from different places and mounting on different places with different rooms in a device, hence, it takes longer time for mounting and assembling.

To reach above object, a process for integrated PC board includes the following:

(a) Supplying an integrated PC board. The integrated PC board is to integrate plural sub-boards to one single board in a device. There are plural elements on the integrated board with plural folding lines for partitioning plural areas for being as sub-boards.

(b) Folding and breaking the plural folding lines to dismantle the integrated board to plural sub-boards, and the sub-boards are able to offer complete function after assembling.

For examinant to further understanding and recognizing the invention, following is the brief description of drawings.

### BRIEF DESCRIPTION OF THE DRAWINGS

FIG. 1A is the front view of prior art device.

FIG. 1B is the side view of prior art device.

FIG. 2A is the front view of upper body of exploded view from FIG. 1 series.

FIG. 2B is the side view of upper body of exploded view from FIG. 1 series.

FIG. 2C is the front view of inner structure of exploded view from FIG. 1 series.

FIG. 2D is the side view of inner structure of exploded view from FIG. 1 series.

FIG. 2E is the front view of lower body of exploded view from FIG. 1 series.

FIG. 2F is the side view of lower body of exploded view from FIG. 1 series.

FIG. 3A is the top view of first board from FIG. 2 series.

FIG. 3B is the side view of first board from FIG. 2 series.

FIG. 4A is the top view of second board from FIG. 2 series.

FIG. 4B is the side view of second board from FIG. 2 series.

FIG. 5A is the top view of integrated board from FIG. 2 series.

FIG. 5B is the side view of integrated board from FIG. 2 series.

### DETAILED DESCRIPTION OF THE INVENTION

The current electrical products are tending to light, thin, short and small, thus any product includes more than one sub-board to bring functions into full play.

In the process of prior art, a single sub-board is as a module to be manufactured, and it is not in efficiency. Thus, to improve this condition is important. The following is the preferred embodiment for the invention.

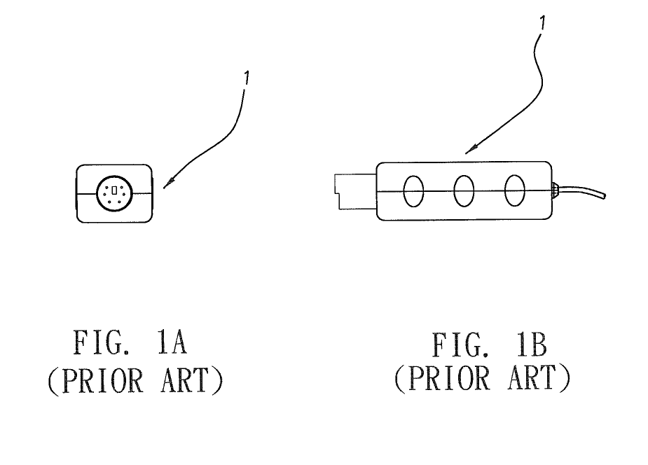

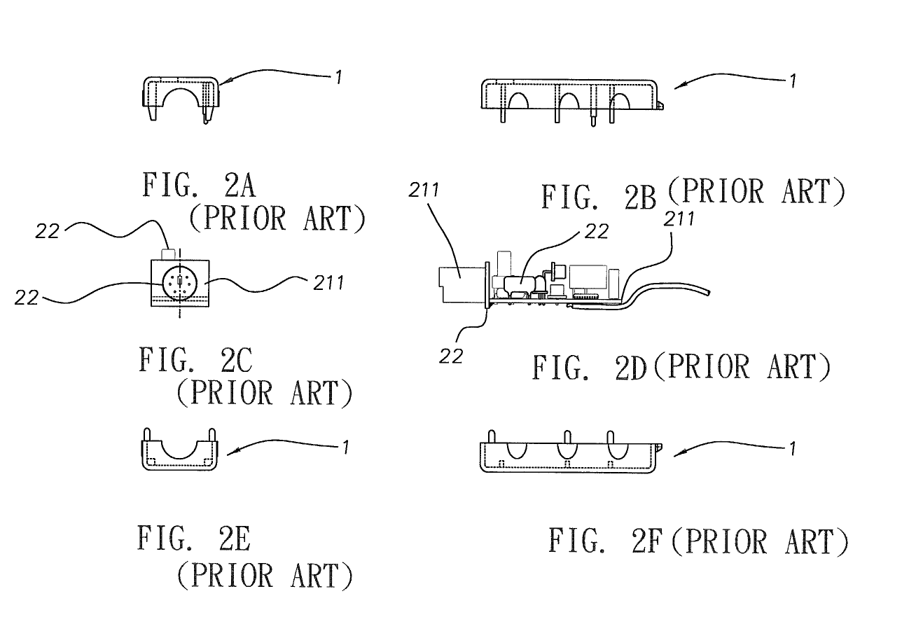

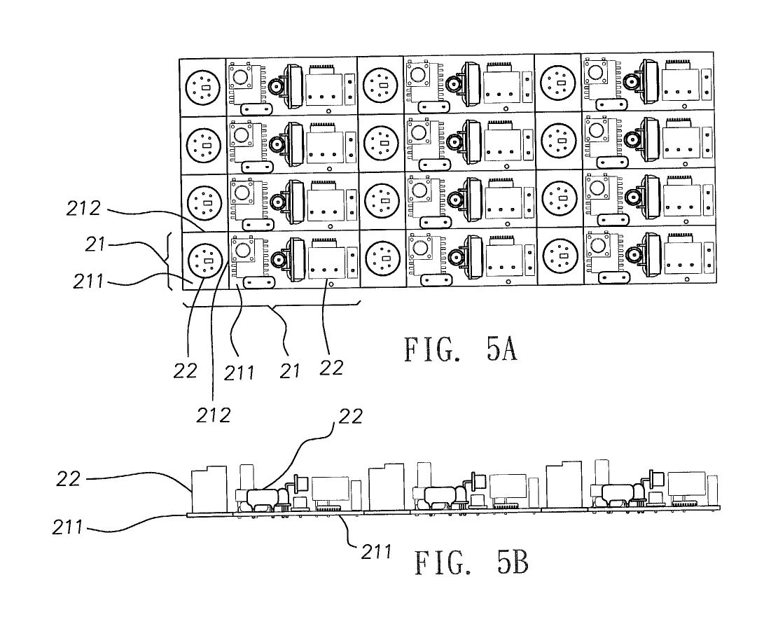

Please refer to FIG. 1 series, FIG. 2 series and FIG. 5 series and a process for integrated PC board includes:

(a) Supplying an integrated PC board 21. The integrated PC board 21 is to integrate plural sub-boards 211 to one single board 21 in a device 1. There are plural elements 22 on the integrated board 21 with plural folding lines 212 for partitioning plural areas for being as sub-boards 211 (showing as FIG. 5 series).

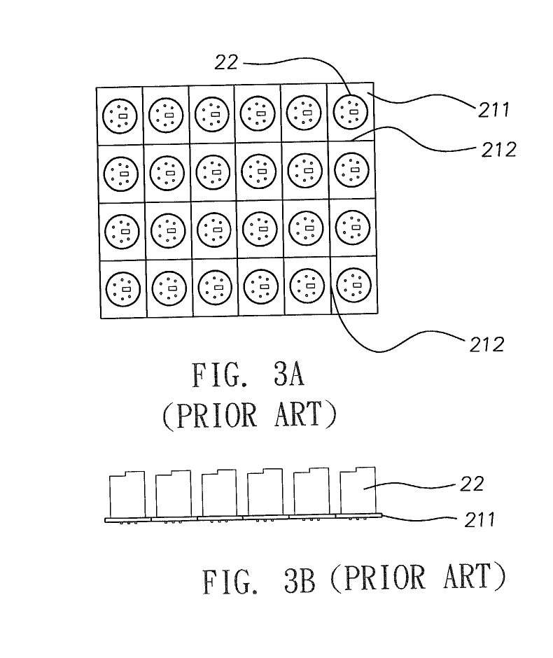

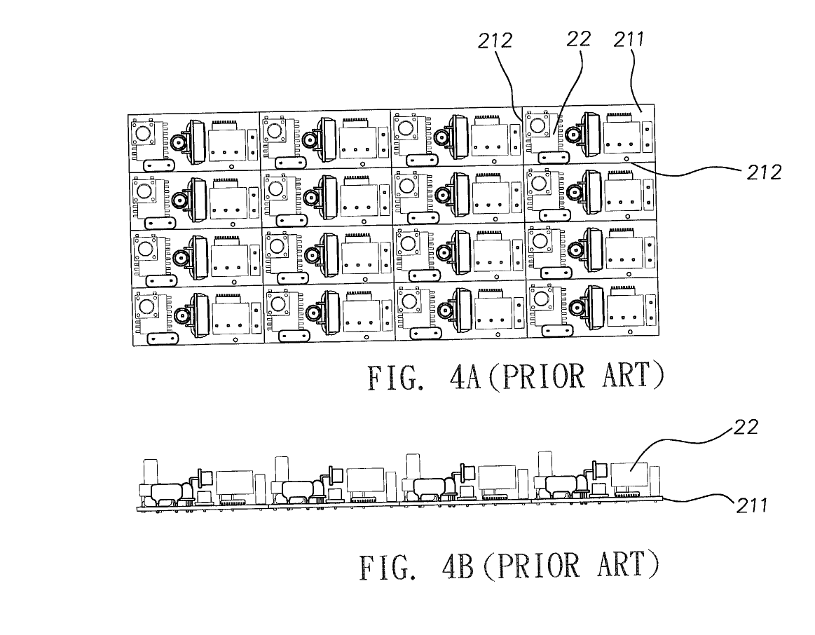

Taking the examples as FIG. 1 series and FIG. 2 series, sub-boards 211 in prior art are separately manufactured (showing as FIG. 3 and FIG. 4 series), and at last assembled in device 1. The invention is to combine sub-boards 211, device 1 needs, to a module and then to be manufactured. Thus, to install different components 22 on a sub-board 211 and to integrate plural sub-boards 211 to be in one integrated board is in one step. The invention simplifies the steps to manufacture integrated board, therefore, raw material is save as well, and the management is easier. For instance, in case of different trays to accept plural sub-boards 211 after installing elements 22, tray is not a need for the invention and the management of material is simplified and convenience.

(b) Folding and breaking the plural folding lines 212 to dismantle the integrated board to plural sub-boards 211, and the sub-boards 211 are able to offer complete function after assembling.

After the integrated board 21 being manufactured, the next step is to assemble it to device 1. Step (a) is that integrating plural sub-boards 211 to the integrated board 21, therefore, the mentioned next step only needs to put into device 1 manually.

As a conclusion, the invention is that integrating the plural sub-boards with same elements 22 to the integrated board 21 firstly, and dismantling the integrated board 21 to plural sub-boards 211 with different elements 22. At the present electrical consumer marketing tending to multiple types and small amount for each product, the invention is a tendency and efficient method.

Of course, the present invention has been described above by taking the case as better embodiment, but implementation scope of the present invention is not really limited to the scope of the embodiment described. All of the modifications, which are made by those whose familiar with the art without departing from the spirit of the invention, belong to the scope of the present invention. Thus the protective scope of the invention is based on the following claims.

What the claim is

1. A process for integrated PC board which includes:
(a) Supplying an integrated PC board. The integrated PC board is to integrate plural sub-boards to one single board in a device. There are plural elements on the integrated board with plural folding lines for partitioning plural areas for being as sub-boards.
(b) Folding and breaking the plural folding lines to dismantle the integrated board to plural sub-boards, and the sub-boards are able to offer complete function after assembling.
